(19) United States
(12) Patent Application Publication
(10) Pub. No.: US 2004/0141295 A1
(43) Pub. Date: Jul. 22, 2004

(54) Circuit module for motor vehicles

(76) Inventors: Georg Fischer, Reifenthal (DE); Andreas Rekofsky, Mintraching (DE)

Correspondence Address: BAKER BOTTS L.L.P., PATENT DEPARTMENT, 98 SAN JACINTO BLVD., SUITE 1500, AUSTIN, TX, 78701-4039, US

(21) Appl. No.: 10/734,443

(22) Filed: Dec. 12, 2003

(30) Foreign Application Priority Data
Dec. 20, 2002 (DE) DE10260242.5

(51) Int. Cl. H05K 5/00

(52) U.S. Cl. 361/752

(57) ABSTRACT

A circuit module for the automobile field has contact wires (7) which are brought out through a wall (3) of the housing and which are made tight by a seal (9) made of a duroplastic or elastomeric material.

### PRIORITY

This application claims foreign priority of the German application DE 10260242.5 filed on Dec. 20, 2002.

### TECHNICAL FIELD OF THE INVENTION

The invention relates to circuit modules for motor vehicles, having a housing accommodating a motor vehicle circuit and having a contact wire brought out of said housing, said contact wire being connected to said motor vehicle circuit.

The invention further relates to an arrangement for contacting the contact wire.

### BACKGROUND OF THE INVENTION

A circuit module of this kind is known from DE 199 07 949 A1. The known circuit module is a motor vehicle control unit comprising a metal base plate on which a ceramic carrier is disposed. On the base plate there is additionally a flexible circuit board surrounding the ceramic carrier on all sides. The flexible circuit board is wire-bonded to the electronic circuit disposed on the ceramic carrier. On the circuit board there is disposed a sealing ring running round the carrier and surmounted by a housing lid covering the circuit board. In the assembled state, the housing lid is riveted onto the continuous sealing ring, thereby pressing it onto the flexible circuit board. As the flexible circuit board and the sealing ring completely surround the carrier, the carrier is made oil-tight, the circuit disposed on the carrier being contactable using conductor paths implemented in the flexible circuit board.

The known circuit module is particularly suitable for incorporating an electronic circuit into the engine or transmission of a motor vehicle. For in addition to being able to operate over a wide temperature range of −40° C. to 150° C., it also provides a high degree of vibration resistance.

One disadvantage of the known circuit module is the high cost of the flexible circuit board, as this circuit board is generally manufactured from expensive polyimide. Material with this composition is generally known, for example, under the trade name KAPTON.

### SUMMARY OF THE INVENTION

Based on this prior art, the object of the invention is to create a circuit module for accommodating circuits in the automobile field which can be less expensively manufactured compared to the prior art. The object of the invention is additionally to specify an arrangement for contacting the circuit modules.

This object can be achieved by a circuit module for motor vehicles, comprising a housing accommodating a motor vehicle circuit and comprising a contact wire brought out of said housing, said contact wire being connected to the motor vehicle circuit, wherein the contact wire is brought out of the housing through a housing wall surface enclosing the contact wire and that the contact wire passes through an elastomeric seal which seals the wall surface against oil and splash water.

The seal can be made of a polyimide-based material or an epoxy-resin-based material. The seal can be positively locked in the wall surface of the housing. The contact wire can be positively locked in the seal. The seal may cover an opening in the wall surface and surmounts a sealing ring running around the opening. The seal may be implemented in a compression element which can be pressed into the wall of the housing. The seal can be implemented as a male connector containing a plurality of contact wires.

The object can also be achieved by a circuit module for motor vehicles, comprising a housing accommodating a motor vehicle circuit and comprising a contact wire brought out of said housing, said contact wire being connected to the motor vehicle circuit, wherein the contact wire is enclosed by a glass seal disposed in a compression element which can be inserted in the wall surface of the housing.

The object can also be achieved by an arrangement for contacting contact wires of an automobile circuit module, comprising connecting leads and contact pins, wherein the connecting leads comprise conductors reinforced by extruded ribbons and are connected to the contact pins.

The object can furthermore be achieved by a method of manufacturing a circuit module, comprising the steps of:

providing a module housing having a base plate;

providing at least one opening in said base plate;

placing an electronic circuit inside said housing on said base plate,

providing a sealing element which includes a connector for providing electrical connection,

sealing said opening with a seal element, and

connecting said connector with said circuit.

The seal can be surrounded by a compression element and can be manufactured of a polyimide-based material, an epoxy-resin-based material, or of glass. The opening may receive a seal with a single connector or multiple connectors separated from each other through the seal. The method may further comprise the steps of:

providing a connecting lead, wherein the connecting lead comprise at least one conductor reinforced by extruded ribbons, and

connecting the conductor with said connector to establish an electrical connection with the electronic circuit.

In the circuit module, the contact wires are not brought out of the housing in a flexible circuit board having an extended surface area as in the prior art. Instead the contact wire is brought out through an opening formed in the wall surface of the housing, said opening being made tight using a seal made of a duroplastic or elastomeric material. An expensive flexible circuit board is not therefore required for the circuit module. The very expensive material required for the seal is concentrated more on the sealing area where it ensures the tightness of the openings in the wall surface. It is therefore likely that devices constructed in this way for accommodating motor vehicle circuits can be manufactured at lower cost compared to the prior art.

In a preferred embodiment, the contact wire is positively locked in the duroplastic or elastomeric seal. The duroplastic or elastomeric seal can also be positively locked in the opening. These measures ensure that the contact wires are fixed in position with respect to the housing.

In a further preferred embodiment, the opening in the housing is sealed by a cover made of a duroplastic or elastomeric material surmounting a sealing ring disposed on the wall surface. A large number of contact wires can be brought out through said cover. Covers implemented in this way can be manufactured separately from the rest of the housing. The cover with the contact wires can then be mounted on the openings provided for the purpose and fixed in position when the motor vehicle circuit is assembled.

In a further preferred embodiment, the contact wire and the seal are implemented in a compression element which can be pressed into a cutout in the wall of the housing. Press-fit connections of this kind have the advantage that no additional fixing means are required. For this embodiment, fused glass can also be used for sealing the contact wires.

At final assembly, the contact wires are preferably brought into contact with connecting leads having conductor paths embedded in extruded ribbons. Leads of this kind have low mass, thereby reducing the vibration loading of the contact wires.

### BRIEF DESCRIPTION OF THE DRAWINGS

The invention will now be explained with reference to the accompanying drawings:

FIG. 1 shows a cross-sectional view of a circuit module for motor vehicles;

FIG. 2 shows the circuit module from FIG. 1 viewed from below;

FIG. 3 is an enlarged cross-section showing the penetration of the contact pin through the wall of the circuit module from FIG. 1;

FIG. 4 shows a cross-section through another embodiment of the penetration of the contact pin through the wall of the circuit module; and

FIG. 5 shows a cross-section through another modified embodiment of the penetration of the contact pin through the wall of the circuit module.

### DETAILED DESCRIPTION OF THE PREFERRED EMBODIMENTS

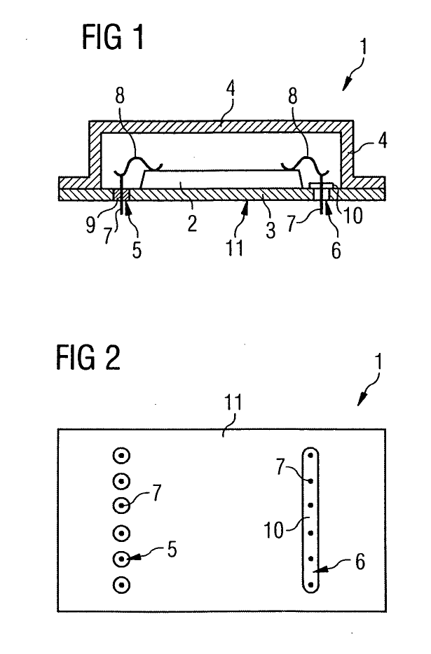

FIG. 1 shows a cross-section through a circuit module 1 accommodating, for example, a circuit for controlling a motor vehicle engine or transmission. The circuit is disposed on a carrier 2 located on a base plate 3. The base plate 3 is surmounted by a cover 4 which seals the carrier 2 against oil and splash water. In the base plate 3 there are provided openings 5 and 6 through which the contact pins 7 are brought out. The contact pins 7 are connected via bond wires 8 to the circuit implemented on the carrier 2. The openings 5 and 6 are sealed by seals 9 and 10, respectively, which will be described in detail below.

FIG. 2 shows a view of an underside 11 of the circuit module 1. Whereas the openings 5 are bores of circular cross-section, the opening 6 is implemented as a slot and the seal 10 is in the form of a male connector comprising a plurality of adjacently disposed contact pins 7.

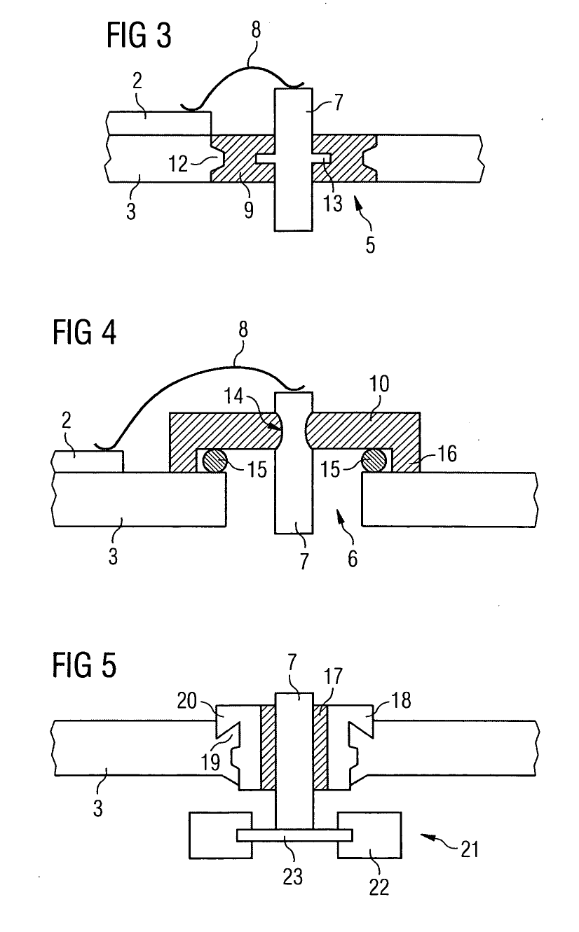

FIG. 3 shows a cross-section through the opening 5 of the circuit module 1 from FIG. 1. The opening 5 is made tight by means of the seal 9 which is positively locked in the opening 5 via lugs 12. In addition, the contact pin 7 has a collar 13 by means of which the contact pin 7 is anchored in the seal 9. Instead of the lug 12 and collar 13, there can also be provided recesses in the base plate 3 and the contact pin 7 through which the contact pin 7 is positively locked in the seal 9 and the seal 9 positively locked in the opening 5. In addition, it is also possible to friction-lock the contact pin 7 in the seal 9.

During manufacture of the circuit module 1, the contact pins 7 are bonded or cast into the base plate 3.

FIG. 4 shows a modified embodiment in the form of a seal 10 implemented as a male connector. The seal 10 extends inside the circuit module 1 over the opening 6 in the base plate 3. The seal 10 holds the contact pin 7 via recesses 14 on the contact pin 7, thereby positively locking the contact pins 7 in the seal 10. Friction locking is also possible between the contact pin 7 and the seal 10.

The seal 10 additionally overlies a sealing ring 15 running round the opening 6 and is suitably fastened to the base plate 3. For example, the seal 10 can be latched to the base plate 3. A particularly secure connection between the seal 10 and the base plate 3 is obtained if the seal 10 is riveted to the base plate 3. To prevent the sealing ring 15 from being pressed out, a stop 16 is implemented on the seal 10.

The seals 10 are preferably produced by injection molding, the contact pins 7 being cast into the seal 10 during this process. The seals 10 are then only mounted on the openings 6 during final assembly.

FIG. 5 shows another embodiment of a seal 17 which holds the contact pin 7 in a compression element 18. Said compression element 18 is a so-called self-clinch plug which is pressed into the base plate 3 in such a way that the material of the base plate 3 flows into recesses 19 under a cutting collar 20. This therefore produces a positive fit between the compression element 18 and the base plate 3. The compression element 18 can be implemented as a single plug with a single contact pin 7 or as a male connector with a plurality of contact pins 7.

The seals 17 are preferably produced by injection molding, the contact pins 7 being cast into the seal 10 during this process. The seals 10 are then only mounted on the openings 6 during final assembly.

FIG. 5 additionally shows a preferred embodiment of a connecting lead 21 which has conductors 23 embedded in extruded ribbons 22. A connecting lead 21 of this kind has a low mass so that the vibration loading of the contact pins 7 is much lower than when using conventional leadframes.

Duroplastics or elastomers are envisioned as materials for the seals 9, 10 and 17. In particular, polyimide- or epoxy-resin-based materials should be used. As the plastic is limited to just the area of the seals 9, 10 and 17, only a small amount of material is used for the seals 9, 10 and 17. The seals 9, 10 and 17 can therefore be inexpensively manufactured.

In a modified embodiment of the seal 17, glass into which the contact pins 7 are sealed is used for this purpose.

In particular the seals 10 and the compression element 18 with the seal 17 can be manufactured separately from the circuit module 1. During manufacture of the circuit module 1, the seal 10 implemented as a male connector and the compression element 18 provided with the seal 17 are then mounted on the base plate 3.

We claim:

1. A circuit module for motor vehicles, comprising a housing accommodating a motor vehicle circuit and comprising a contact wire brought out of said housing, said contact wire being connected to the motor vehicle circuit, wherein the contact wire is brought out of the housing through a housing wall surface enclosing the contact wire and that the contact wire passes through an elastomeric seal which seals the wall surface against oil and splash water.

2. The circuit module according to claim 1, wherein the seal is made of a polyimide-based material.

3. The circuit module according to claim 1, wherein the seal is made of an epoxy-resin-based material.

4. The circuit module according to claim 1, wherein the seal is positively locked in the wall surface of the housing.

5. The circuit module according to claim 1, wherein the contact wire is positively locked in the seal.

6. The circuit module according to claim 1, wherein the seal covers an opening in the wall surface and surmounts a sealing ring running around the opening.

7. The circuit module according to claim 1, wherein the seal is implemented in a compression element which can be pressed into the wall of the housing.

8. The circuit module according to claim 1, wherein the seal is implemented as a male connector containing a plurality of contact wires.

9. A circuit module for motor vehicles, comprising a housing accommodating a motor vehicle circuit and comprising a contact wire brought out of said housing, said contact wire being connected to the motor vehicle circuit, wherein the contact wire is enclosed by a glass seal disposed in a compression element which can be inserted in the wall surface of the housing.

10. An arrangement for contacting contact wires of an automobile circuit module, comprising connecting leads and contact pins, wherein the connecting leads comprise conductors reinforced by extruded ribbons and are connected to the contact pins.

11. A method of manufacturing a circuit module, comprising the steps of:
providing a module housing having a base plate;
providing at least one opening in said base plate;
placing an electronic circuit inside said housing on said base plate,
providing a sealing element which includes a connector for providing electrical connection,
sealing said opening with a seal element, and
connecting said connector with said circuit.

12. The method as in claim 11, wherein the seal is surrounded by a compression element.

13. The method as in claim 11, wherein the seal is manufactured of a polyimide-based material.

14. The method as in claim 11, wherein the seal is manufactured of an epoxy-resin-based material.

15. The method as in claim 11, wherein the seal is manufactured of glass.

16. The method as in claim 11, wherein the opening receives a seal with a single connector.

17. The method as in claim 11, wherein the opening receives a seal with multiple connectors separated from each other through the seal.

18. The method as in claim 11, further comprising the steps of:
providing a connecting lead, wherein the connecting lead comprise at least one conductor reinforced by extruded ribbons,
connecting the conductor with said connector to establish an electrical connection with the electronic circuit.
